(19) United States
(12) Patent Application Publication
(10) Pub. No.: US 2011/0186829 A1
(43) Pub. Date: Aug. 4, 2011

(54) Surface Treated Substrates for Top Gate Organic Thin Film Transistors

(75) Inventors: Jeremy Burroughes, Cambridge (GB); Julian Carter, Cambridgeshire (GB); Jonathan Halls, Cambridge (DE); Thomas Kugler, Cambridge (GB); Christopher Newsome, Cambridgeshire (GB)

(73) Assignee: Cambridge Display Technology Limited, Cambridgeshire (GB)

(21) Appl. No.: 13/056,332

(22) PCT Filed: Aug. 7, 2009
(86) PCT No.: PCT/GB2009/001941

§ 371 Date: Apr. 21, 2011

(30) Foreign Application Priority Data
Aug. 8, 2008 (GB) 0814534.4

(51) Int. Cl. H01L 51/10; H01L 51/40

(52) U.S. Cl. 257/40; 438/99; 257/E51.005; 257/E51.001

(57) ABSTRACT

A method of forming a top gate transistor comprising the steps of providing a substrate carrying source and drain electrodes defining a channel region therebetween; treating at least part of the surface of the channel region to reduce its polarity; and depositing a semiconductor layer in the channel.

### FIELD OF THE INVENTION

The present invention relates to transistors, in particular organic thin film transistors.

### BACKGROUND OF THE INVENTION

Transistors can be divided into two main types: bipolar junction transistors and field-effect transistors. Both types share a common structure comprising three electrodes with a semiconductive material disposed therebetween in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semiconductive material which conducts positive charge carriers (holes) or negative charge carriers (electrons) respectively. The semiconductive material may be selected according to its ability to accept, conduct, and donate charge. The ability of the semiconductive material to accept, conduct and donate holes or electrons can be enhanced by doping the material.

For example, a p-type transistor device can be formed by selecting a semiconductive material which is efficient at accepting, conducting, and donating holes, and selecting a material for the source and drain electrodes which is efficient at injecting and accepting holes from the semiconductive material. Good energy-level matching of the Fermi-level in the electrodes with the HOMO level of the semiconductive material can enhance hole injection and acceptance. In contrast, an n-type transistor device can be formed by selecting a semiconductive material which is efficient at accepting, conducting, and donating electrons, and selecting a material for the source and drain electrodes which is efficient at injecting electrons into, and accepting electrons from, the semiconductive material. Good energy-level matching of the Fermi-level in the electrodes with the LUMO level of the semiconductive material can enhance electron injection and acceptance.

Transistors can be formed by depositing the components in thin films to form a thin film transistor (TFT). When an organic material is used as the semiconductive material in such a device, it is known as an organic thin film transistor (OTFT). Organic semiconductors are a class of organic molecules having extensively conjugated delocalised pi systems allowing for the movement of electrons.

OTFTs may be manufactured by low cost, low temperature methods such as solution processing. Moreover, OTFTs are compatible with flexible plastic substrates, offering the prospect of large-scale manufacture of OTFTs on flexible substrates in a roll-to-roll process.

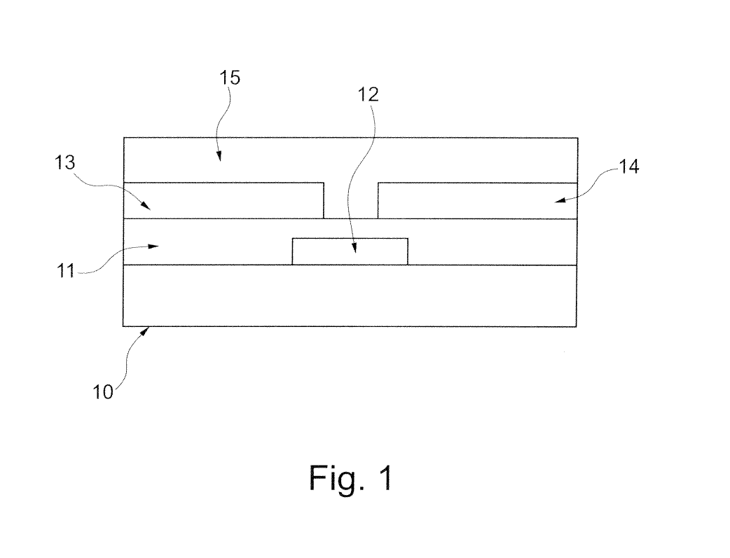

With reference to FIG. 1, the general architecture of a bottom-gate organic thin film transistor (OTFT) comprises a gate electrode 12 deposited on a substrate 10. An insulating layer 11 of dielectric material is deposited over the gate electrode 12 and source and drain electrodes 13, 14 are deposited over the insulating layer 11 of dielectric material. The source and drain electrodes 13, 14 are spaced apart to define a channel region therebetween located over the gate electrode 12. An organic semiconductor (OSC) material 15 is deposited in the channel region between the source and drain electrodes 13, 14. The OSC material 15 may extend at least partially over the source and drain electrodes 13, 14.

Alternatively, it is known to provide a gate electrode at the top of an organic thin film transistor to form a so-called top-gate organic thin film transistor. In such an architecture, source and drain electrodes are deposited on a substrate and spaced apart to define a channel region therebetween. A layer of an organic semiconductor material is deposited in the channel region between the source and drain electrodes and may extend at least partially over the source and drain electrodes. An insulating layer of dielectric material is deposited over the organic semiconductor material and may also extend at least partially over the source and drain electrodes. A gate electrode is deposited over the insulating layer and located over the channel region.

The performance of organic semiconductors and transistors containing those semiconductors is typically assessed by measurement of their “charge mobility” (cm² V⁻¹s⁻¹) which is also known as “electron mobility” or “hole mobility” depending on whether the device is an n-channel or p-channel device This measurement relates to the drift velocity of charge carriers to an applied electric field across a material.

Treatment of the dielectric layer of bottom-gate devices is known in the art for the purpose of reducing contact angle for the organic semiconductor and improving molecular ordering of the semiconductor (in particular to achieve higher crystallinity).

For example, Sirringhaus et. al [Nature vol 401, p 685-688, 1999] discloses a self-assembled monolayer (SAM) pre-treated silicon dioxide insulator layer with a methyl termination group (created by using hexamethyldisilazane) that influences the morphology of P3HT resulting in an improvement in the field effect mobility of the OTFT to 0.1 cm²/Vs. This approach has also been made by Wu et. al [Appl. Phys. Lett. Vol 86, 142101, 2005] using a number of alkyl chain SAMs.

Kumaki et. al. [Appl. Phys. Lett. Vol 90, 133511 (2007)] discloses the use of a phenethyltrichlorosilane for the purpose of pre-treating the dielectric layer of a bottom gate device with a silicon dioxide dielectric. The semiconductor used in this work was a thermally evaporated film of pentacene. The resultant improvements in device performance are attributed to a reduction in the adsorption of water at the silicon dioxide layer that would lead to the formation of trap sites.

A phenyl terminated SAM (created using phenyltrichlorosilane) has been investigated by Rawcliffe et. al [Chem. Commun., 871-73, 2008] on a bottom gate SiO2 device architecture using a fused polythiophene.

A combination of channel and electrode pre-treatments of a bottom-gate device using self assembled monolayers for an organic semiconducting layer of Bis(triisopropylsilylethnyl) pentacene (TIPS Pentacene) is disclosed in Park et. al Appl. Phys. Lett., Vol 91, 063514 (2007). In this work the SAM selected for treating the electrode contact was pentafluorobenzenethiol (PFB thiol), and hexamethyldisilazane (HMDS) for the surface of the silicon dioxide dielectric layer forming the channel region of the device.

The aforementioned prior art relates to bottom gate devices. In development of top gate OTFT devices, the present inventors have discovered that such devices can suffer from high off-current and poor mobility. The present inventors have identified that these problems arise at least in part from groups present on the substrate surface in the channel, e.g. polar groups on the substrate surface in the case of a glass substrate. These groups may arise from the cleaning processes (UV ozone and Oxygen plasma etc) and may include carboxylic acid groups and —OH surface groups. In some cases a UV ozone or Oxygen plasma process may also be used to reduce contact resistance by modifying the metal surface.

These polar species may lead to doping of the organic semiconductor at the interface with the glass substrate, leading to the formation of a conducting “back channel” that allows a source drain current to flow when the TFT is set to its “off state”. This increases the off current, reducing the on/off ratio and the sub-threshold swing. These reductions in performance reduce the useful range of applications for these devices. This effect is particularly problematic for a top gate device wherein the semiconductor/substrate interface (“back channel”) is remote from the semiconductor/dielectric interface (the active channel in the transistor). In contrast, in bottom gate devices the “substrate”/semiconductor interface is also the dielectric/semiconductor interface. As a result, it is more difficult to deplete the induced charges at the substrate/semiconductor interface in top-gate devices, with the result that off currents are higher.

The present invention seeks to reduce off current and increase the mobility of top-gate devices.

### SUMMARY OF THE INVENTION

In a first aspect the invention provides a method of forming a top gate transistor comprising the steps of providing a substrate carrying source and drain electrodes defining a channel region therebetween; treating at least part of the surface of the channel region to reduce its polarity; and depositing a semiconductor layer in the channel.

An organic thin film transistor can be fabricated on a rigid or flexible substrate. Rigid substrates may be selected from glass or silicon and flexible substrates may comprise thin glass or plastics such as poly(ethylene-terephthalate) (PET), poly(ethylene-naphthalate) PEN, polycarbonate and polyimide.

The organic semiconductive material may be made solution processable through the use of a suitable solvent. Exemplary solvents include mono- or poly-alkylbenzenes such as toluene and xylene; tetralin; and chloroform. Preferred solution deposition techniques include spin coating and ink jet printing. Other solution deposition techniques include dip-coating, roll printing and screen printing. Preferred organic semiconductors include pentacene and fused thiophene. Preferred fused thiophenes include thiophene fused to one or more further aryl groups, preferably one or more aryl groups selected from thiophene (e.g. to form dithiophene or dithienothiophene) and benzene. The organic semiconductor may optionally be substituted. Preferably, the organic semiconductor is substituted with a solubilising group such as alkyl, alkoxy or trialkylsilylethynyl. In one preferred embodiment the organic semiconductor layer is formed from a blend of materials, such as a small molecule and a polymer.

The length of the channel defined between the source and drain electrodes may be up to 500 microns, but preferably the length is less than 200 microns, more preferably less than 100 microns, most preferably less than 20 microns.

The gate electrode can be selected from a wide range of conducting materials for example a metal (e.g. gold, aluminium, silver etc) or metal oxide ceramic compound (e.g. indium tin oxide). Alternatively, conductive polymers may be deposited as the gate electrode. Such conductive polymers may be deposited from solution, preferably using an additive process such as ink jet printing or other solution deposition techniques discussed above.

The insulating layer comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include SiO₂, SiNx and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor, it should not result in dissolution of the organic semiconductor. Likewise, the dielectric material should not be dissolved if the organic semiconductor is deposited onto it from solution. Techniques to avoid such dissolution include: use of orthogonal solvents for example use of a solvent for deposition of the uppermost layer that does not dissolve the underlying layer; and cross linking of the underlying layer.

The thickness of the insulating layer is preferably less than 2 micrometres, more preferably less than 500 nm.

The treatment of the channel according to the present invention forms a layer that covers at least some, and preferably all, of the channel region. Alternatively or additionally, the layer covers substantially the entire surface of the substrate.

The layer may comprise a polymer organic layer, preferably a polymer layer. Alternatively, the layer comprises a self-assembled layer, such as a self-assembled monolayer.

Preferably, the reactive species reacts with the polar groups on the substrate surface to form a self-assembled layer. The polar groups are typically groups capable of undergoing dissociation such as deprotonation. Preferably, the reactive species reacts with hydroxyl or acid polar groups on the substrate surface to form ether or ester groups respectively. In this way, the polar groups that give rise to high off current are converted to a non-polar form. The reduction in polarity at the surface of the channel is apparent, for example, from a reduced contact angle of the organic semiconductor with the channel after treatment as compared to before treatment.

Preferably, the reactive species comprises a reactive group for reacting with dissociating groups on the substrate surface and a non-polar group.

Consequently, the reactive species reacts with said polar groups to form a residue having at least one non-polar group such as linear, branched or cyclic alkyl and optionally substituted aryl end groups, i.e. groups that have an affinity for the organic semiconductor material. Preferably, the non-polar group is devoid of any dissociating groups, such as hydroxyl or acid groups. Preferably, the non-polar group is a hydrocarbon group. Preferably, the non-polar group is a conjugated group and may be a semiconducting group. Such residues may comprise the structure:

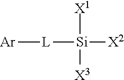

where Ar is an aryl group, L is a linker group or single bond and where X¹ represents a bond to the surface of the substrate and X² and X³, if present, independently represent a bond to the surface of the substrate or a substituent group selected from the group: optionally substituted straight, branched or cyclic alkyl or alkenyl group having from 1 to 10 carbon atoms, or aryl group. It will be appreciated that other non-polar groups such as an alkyl group or optionally substituted acene group may be used in place of the Ar group. The bond X¹ (and, where present, X² and X³) is typically formed by reaction of a leaving group attached to the Si atom of the reactive species. A preferred leaving group is reactive halogen, preferably Cl.

Preferably, the linker group L comprises a substituted or unsubstituted, straight, branched or cyclic alkyl group of 1 to 10 carbon atoms.

In some preferred embodiments, the residues comprise one or more of the structures shown below:

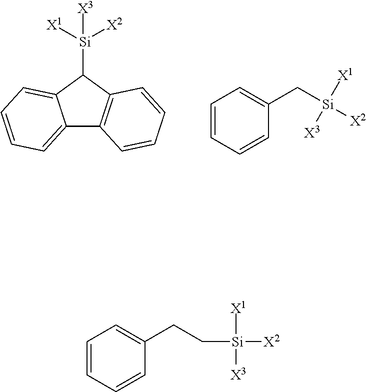

where X¹ represents a bond to the surface of the substrate and X² and X³, if present, independently represent a bond to the surface of the substrate or a substituent group selected from the group: optionally substituted straight, branched or cyclic alkyl or alkenyl group having from 1 to 10 carbon atoms or aryl group.

In some embodiments, the invention comprises the step of treating the source and drain electrodes with a compound for reducing the contact resistance of the electrodes, either before or after the treatment of the channel region. This forms an electrode treatment layer covering at least some of the surface of one or both of the source electrode and drain electrode. The electrode treatment layer may comprise a polymer layer. More preferably, the electrode treatment layer comprises a self-assembled layer, such as a self-assembled monolayer. Preferably, the compound for reducing the contact resistance comprises a compound capable of chemically binding to the source and drain electrodes. More preferably, the compound comprises a thiol or disulfide and the source and drain electrodes comprise gold, silver, copper or alloys thereof.

In some embodiments, the electrode treatment layer comprises residues presenting a negative dipole moment at the surface of the electrode or electrodes, such as halogenated or perhalogenated residues. In other embodiments, the electrode contact layer comprises residues presenting a positive dipole moment at the surface of the electrode or electrodes, such as alkane residues.

Preferably, the source and/or drain electrodes are comprised of copper, silver or gold.

In some preferred embodiments, the electrode contact layer comprises residues comprising the structures:

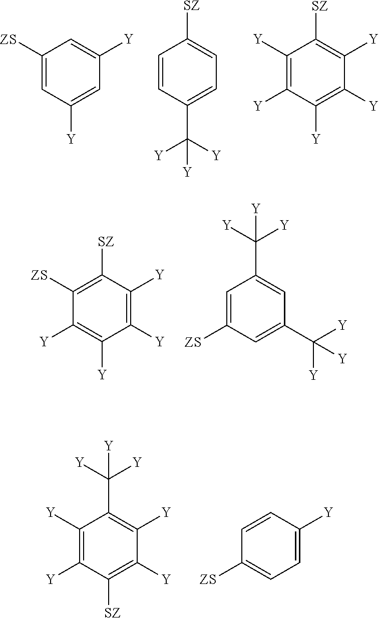

where Y represents an electron withdrawing group, preferably selected from the group consisting of nitro, cyano, alkoxy (preferably methoxy) and halogen, preferably fluorine, and Z represents a bond between one or more sulphur atoms and the surface of the electrode.

In an alternative embodiment of the first aspect, the reactive species may comprise a reactive group that forms a free-radical upon activation. This is particularly beneficial for plastic substrates wherein treatments such as UV-ozone treatment may damage the plastic surface. The reactive free-radical species may react with the damaged surface and thus provide a “repaired” surface for deposition of the semiconductor.

In a second aspect the invention provides a transistor obtainable by the method of the first aspect of the invention.

In a third aspect the invention provides a top gate transistor having a channel region comprising an organic layer between the substrate and the semiconductor layer. The organic layer may be a layer formed by treatment as described in the first aspect of the invention.

In a fourth aspect the invention provides a method of forming a top gate transistor according to the third aspect of the invention comprising the steps of providing a substrate carrying source and drain electrodes defining a channel region therebetween; depositing an organic layer over the substrate in the channel region; and depositing a semiconductor layer on the organic layer.

In a fifth aspect the invention provides a method of forming a thin-film transistor comprising the steps of providing source and drain electrodes defining a channel therebetween; treating at least part of the surface of the channel region to reduce the polarity thereof; and subsequently treating at least part of the surface of the source and drain electrodes to reduce the contact resistance thereof.

Each of the treatment steps of the fifth aspect of the invention may be as defined in any of the first to third aspects of the invention.

The fifth aspect of the invention may be applied to formation of either a top-gate device or a bottom gate device.

FIG. 1 shows a prior art transistor.

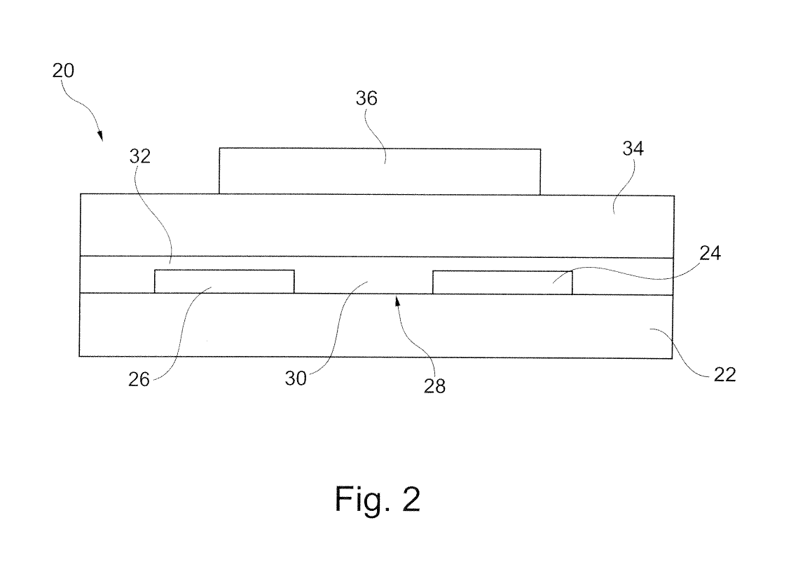

FIG. 2 shows a transistor according to the invention.

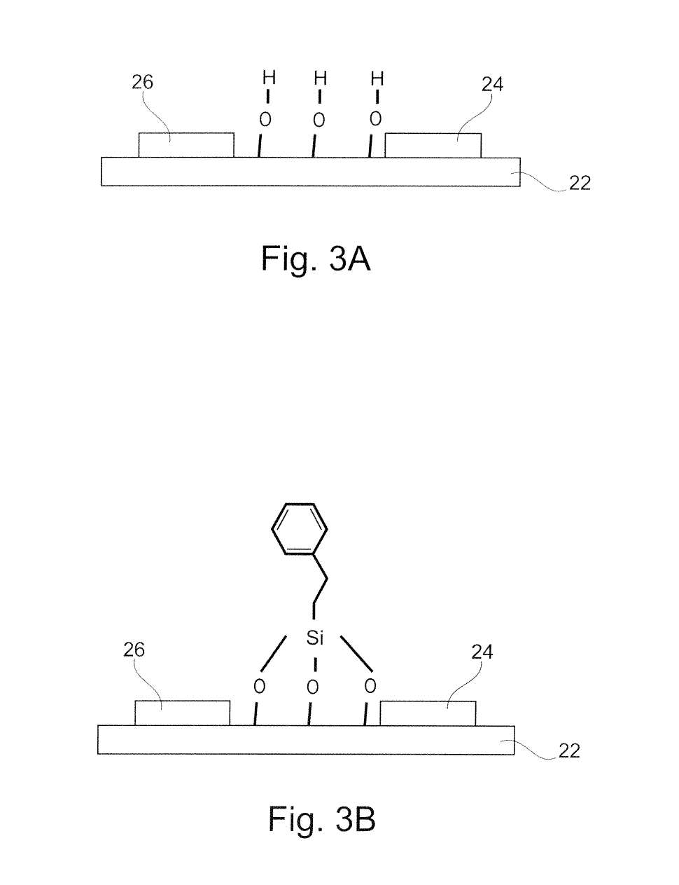

FIG. 3 shows stages in the manufacture of a transistor.

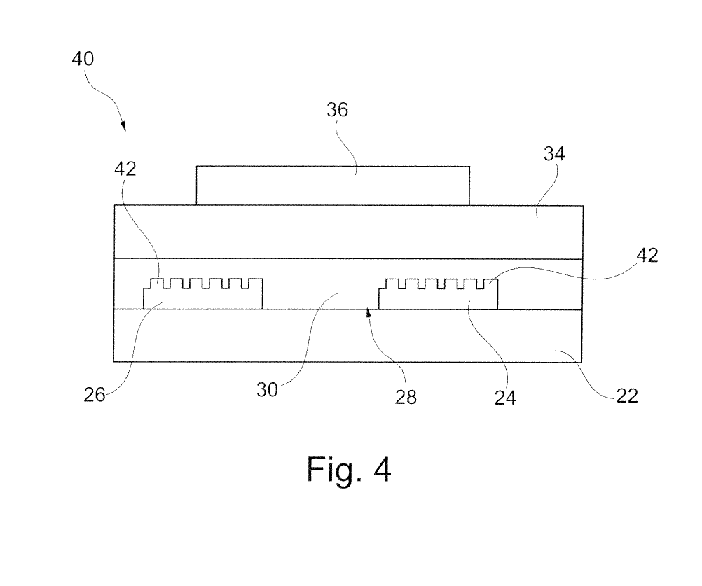

FIG. 4 shows a further transistor according to the invention.

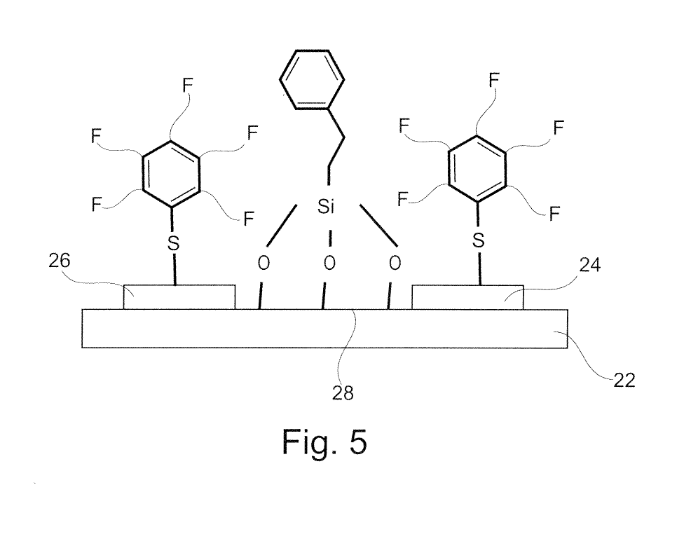

FIG. 5 shows a stage in the manufacture of a transistor.

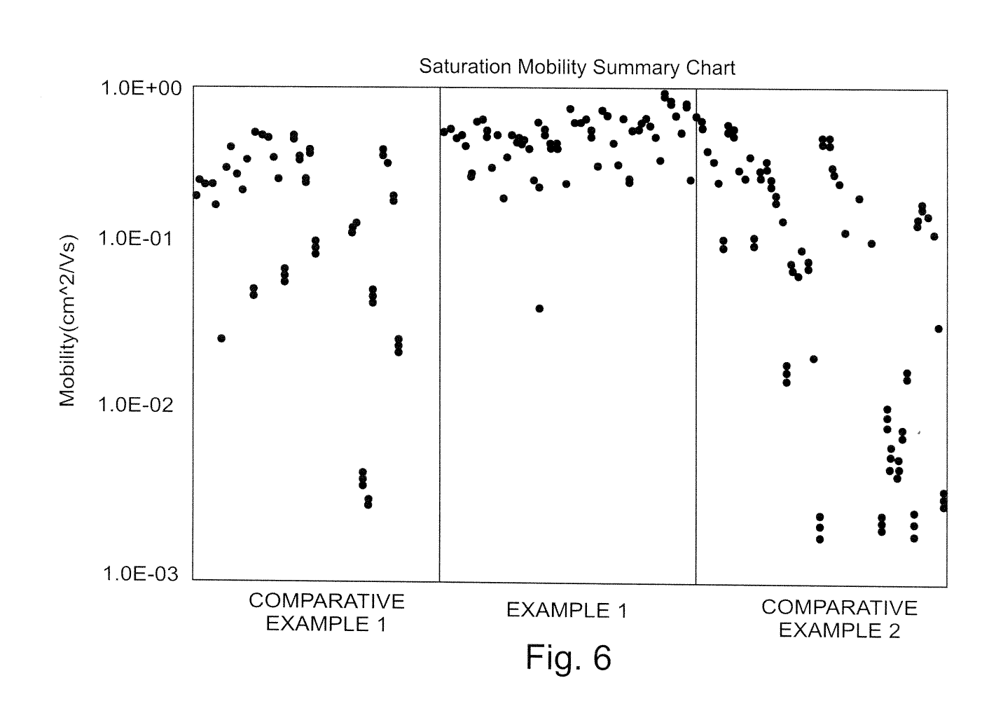

FIG. 6 shows a chart of the mobility of transistors according to the invention and transistors of the prior art.

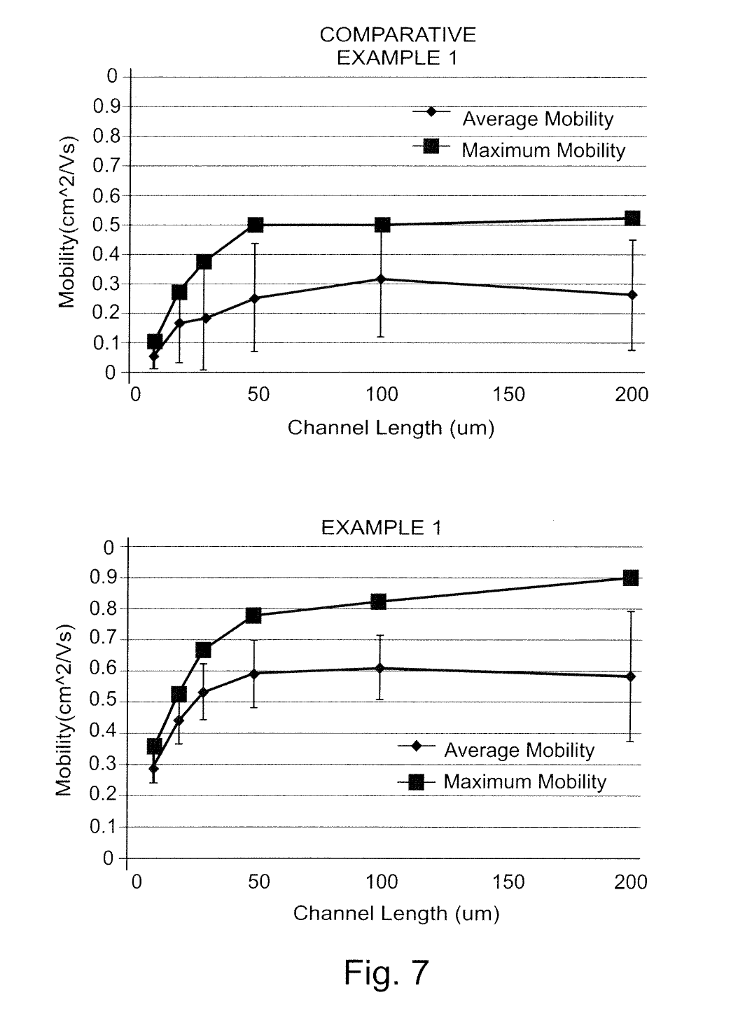

FIG. 7 shows a plot of the mobility against channel length of transistors according to the invention and transistors of the prior art.

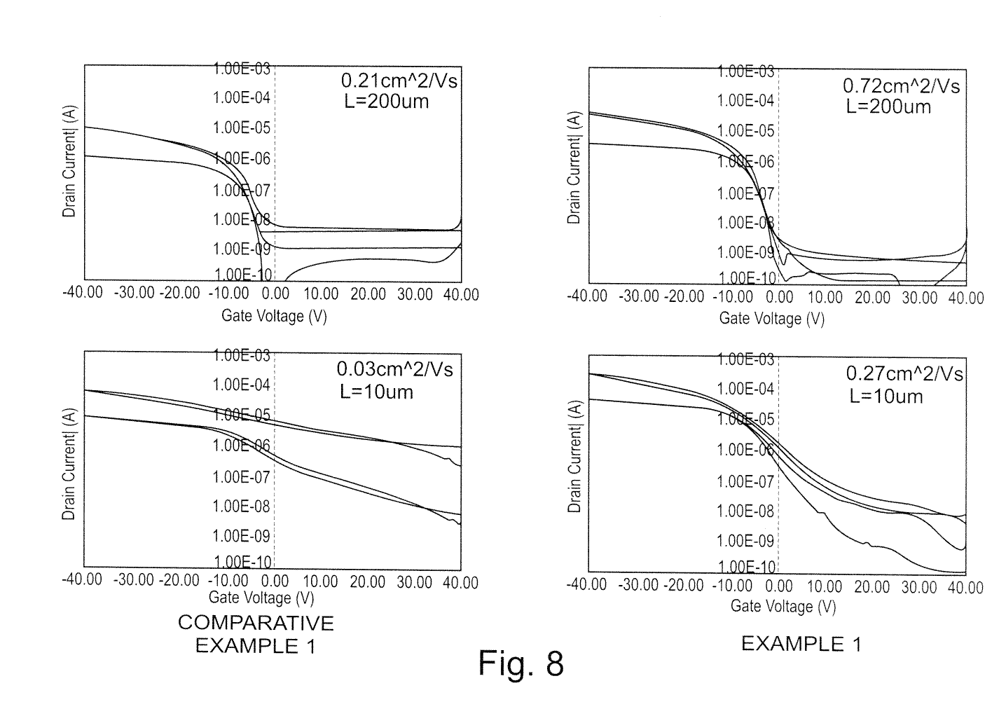

FIG. 8 shows transfer characteristics in linear and saturation regimes for transistors according to the invention and transistors of the prior art.

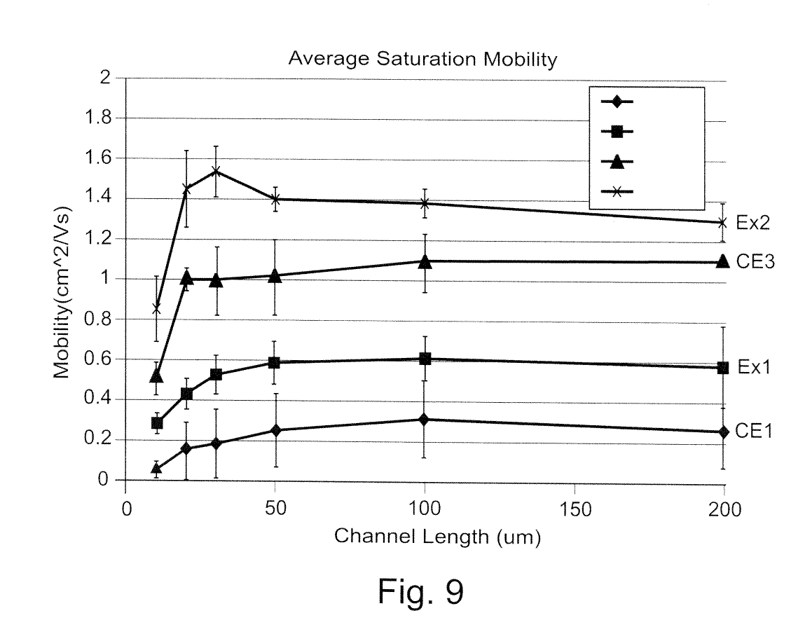

FIG. 9 shows a plot of the mobility against channel length of transistors according to the invention and transistors of the prior art.

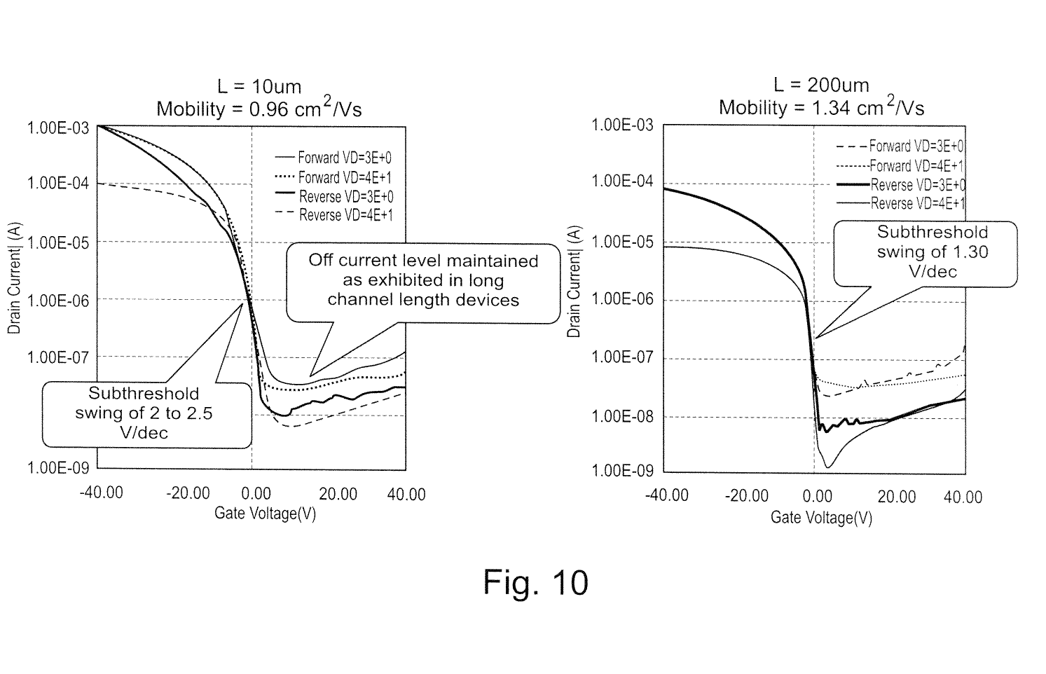

FIG. 10 transfer characteristics in linear and saturation regimes for transistors according to the invention.

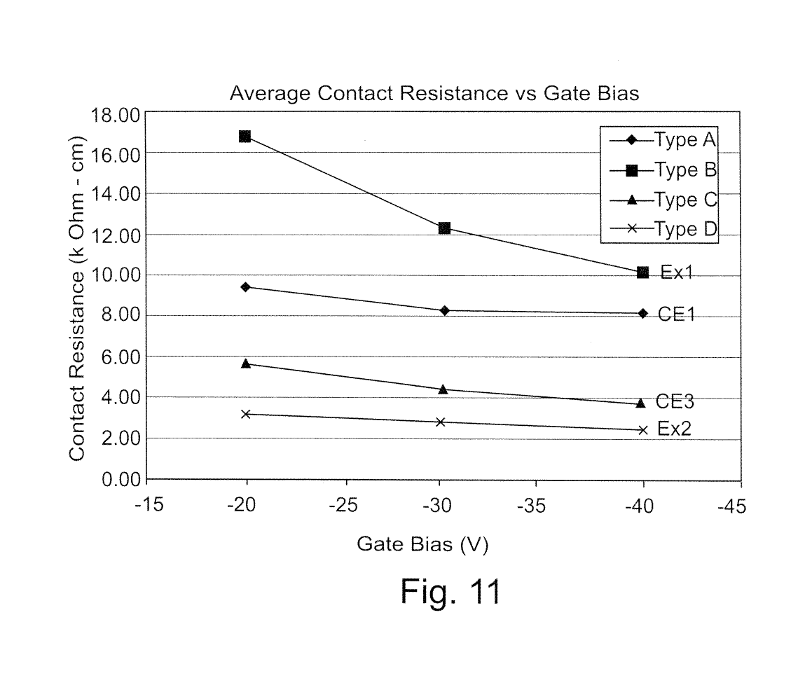

FIG. 11 shows a plot of contact resistance against gate bias for transistors according to the invention and a transistor of the prior art.

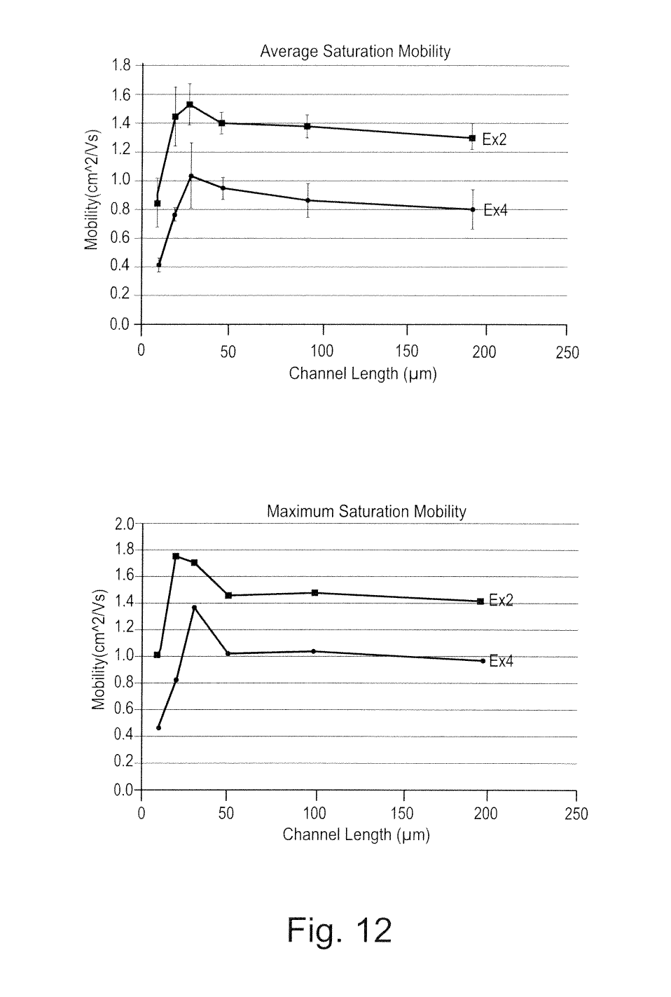

FIG. 12 shows plots of mobility against channel length of transistors according to the invention.

A schematic diagram of a transistor according to a first embodiment of the present invention is shown in FIG. 2.

The transistor 20 comprises a planar substrate 22, which is made from glass, for example a silicate glass, plastic or spin-on glass. Affixed to the substrate 22 are a gold source electrode 24 and a gold drain electrode 26, which define a channel 28 therebetween. A non-polar self assembled layer 30 lines the surface of the substrate 22.

A layer of semiconducting material 32 covers the source electrode 24 and drain electrode 26 and contacts the self assembled layer 30.

A layer of dielectric material 34 is positioned between the semiconducting material 32 and a gate electrode 36.

The provision of the non-polar self assembled layer 30 affords an increase in mobility and a widening of the on/off current ratio, crucial to the switching operation of devices such as pixel elements in a display.

Without wishing to be bound by any particular theory, it is postulated that the native surface of the substrate 30 typically contains polar hydroxyl groups. Moreover, the generation of polar species from the decomposition of organic residues such as photoresists can yield species such as carboxylic acid groups. The presence of these hydrophilic groups creates a doping effect of the semiconductor layer in the channel, leading to increased conductivity. Thus, in short-channel (<20 micron) devices under high source-drain fields the off-current is dramatically increased. By protecting the semiconductor from the influence of these polar groups, the doping effect is drastically reduced.

FIG. 3 shows schematic diagrams of the substrate 22 before and after the non-polar self assembled layer is applied.

FIG. 3A shows the hydroxyl groups at the surface of the substrate, while FIG. 3B shows a phenethyl silane residue, a preferred residue for the formation of the non-polar layer 30, bonded to the substrate and thus capping the polar groups.

The first stage in the manufacture of such a transistor is preferably the preparation of the source and drain electrodes 24, 26. This may be achieved by well known metal patterning techniques such as depositing a lift-off negative photoresist onto a substrate and exposing and developing it to form the intended shape of the electrodes; etching a layer of the source-drain metal; or printing conductive contacts.

A thin, say 3 nm, chrome layer is applied to the etched pattern to act as an adhesive, followed by a thicker, say around 30 nm layer of gold.

The photoresist is then lifted off to leave the patterned electrode features remaining on the substrate. The electrodes preferably provide a channel of between 5 μm or less and 200 μm in length and of up to 2 mm in width.

The substrate is then cleaned in a UV ozone or Oxygen plasma tool for around 10 minutes. This removes and/or decomposes any organic contaminants present at the surface of the substrate 22 and the electrodes 24, 26 and leaves the surface of the substrate exposed. However, this treatment will typically result in the formation of a polar substrate surface (especially in the case of a glass substrate), and damage to the substrate (especially in the case of a glass substrate).

Following cleaning the non-polar layer 30 can be applied. A solution of a mono, di or tri halide of the desired aryl silane is prepared and then contacted with the surface of the substrate. The silane solution may be dispensed on top of the substrates from a syringe, aerosol, printer or other technique, or alternatively the substrate may be immersed in the silane solution. After a period of up to few minutes, the solution is removed by, for example, spinning in a spin-coating machine.

The surface of the substrate 22 is then washed to remove any by-products of the coating reaction and any unreacted arylsilane, leaving behind that attached self assembled layer. Any remaining solvent may also be removed by spinning in a spin-coating machine, or by another technique.

The semi-conducting material is deposited by spin coating a film of an organic semiconductor solution onto the substrate and drying off the remaining host solvent. Alternative methods for coating the OSC include, and are not limited to, ink jet printing, spray coating, LITI and flexographic coating.

A dielectric material, such as Teflon® AF2400 (DuPont) is then spin-coated onto the semiconducting layer and dried.

Finally, a gate electrode is added by depositing a thin layer, say 3 nm, of chrome and a thicker layer, say 30 nm to 50 nm, of aluminium through a shadow mask onto the dielectric layer.

A transistor according to a second embodiment of the invention is shown in FIG. 4.

The transistor 40 is structured substantially as described above, though as well as having a non-polar, self assembled layer on the substrate 22, the transistor 40 also comprises an electrode contact layer 42 on the source and drain electrodes 24, 26.

The electrode contact layer 42 preferably comprises a self assembled layer, such as a self assembled monolayer, of residues terminated by a fluoroarylene.

FIG. 5 shows a substrate 22 and source and drain electrodes 24, 26, the substrate having applied a layer of phenylethylsilane. The source and drain electrodes carry a self assembled layer of perfluorobenzenethiol, a preferred electrode contact layer residue.

The negative dipole moment provided by the perfluorinated surface layer of the electrodes reduces the hole injection barrier to the semiconductor proportionally to its dipole strength. The contact modification may also modify the morphology of the OSC by seeding nucleation of crystals from the electrode edges.

The transistor 20 is produced in substantially the same manner as described above in relation to the first embodiment, save for the step of fabricating the electrode treatment layer, which may take place before, or more preferably after, the fabrication of the channel treatment layer.

The electrode treatment layer is fabricated in much the same way as the channel treatment layer. A solution of the desired substituted-aryl-thiol or substituted-aryl-disulfide is made up and spread over the surface of the electrodes. After waiting for up to several minutes the electrode treatment layer is complete and the excess solution is removed by spinning in a spin-coating machine. A rinse is then performed and any excess solvent is removed via spin-coating or other technique.

While mono-thiols can be used to successfully create electrode treatment layers, di- or tri-thiols have a higher thermal stability and thus also have a higher resistance to desorption from the metal surface.

### EXAMPLE 1

A top gate thin film transistor device having a channel treatment layer was fabricated in a manner as described below:

A pair of source and drain electrodes were deposited onto the surface of a glass substrate. A 3 nm layer of chrome was evaporated onto the pattern followed by a 30 nm layer of gold. The photoresist was then removed to leave the electrodes attached to the surface of the glass substrate. The glass substrate was then cleaned in a UV ozone tool for 10 minutes.

A solution for preparation of the channel treatment layer was prepared by adding 0.05 ml of phenethyltrichlorosilane to 10 ml of toluene and agitating to ensure a homogenous solution is obtained. The solution was then dispensed onto a glass substrate through a 0.45 um filter to completely cover the substrate, and left for a period of 2 minutes to allow a sufficiently dense channel treatment layer to condense on the surface of the glass.

The channel treatment solution was removed by spin coating at 1000 rpm for a period of 30 seconds.

The substrate was rinsed with the host solvent, toluene to remove the HCl produced by the reaction of the assembly of the channel treatment layer. This toluene was dispensed through a 0.45 um filter and was left on the substrate for a period of 5 seconds before commencing a spin coating cycle. Further toluene (10 ml) was dispensed across the substrate throughout a spin coating cycle at 1000 rpm for 30 seconds. The channel treatment step was completed at this stage.

A semiconductor layer was deposited by spin coating a film of Bis(tri sopropylsilylethnyl) pentacene (TIPS pentacene) from a tetralin solution comprising 20 mg of solid per 1 ml of solvent at 1000 rpm for 60 seconds. The film was both spin coated and dried in a dry nitrogen atmosphere at 10° C. for 5 minutes to remove the host solvent from the film.

A dielectric layer of 250 nm in thickness was also spin coated from solution. A solution of DuPont Teflon® AF2400 in perfluorinated solvent such as the solvent FC-75 available from 3M under the trade name Fluorinert was used (20 mg of solid per 1 ml of solvent), with spin coating made at 1000 rpm for 60 seconds. The dielectric layer was then dried at 80° C. for 10 minutes.

To complete the device, a gate electrode was deposited by thermal evaporation through a shadow mask. 3 nm of Chrome were evaporated through the mask, followed by between 30 nm and 50 nm of Aluminium.

Transistors having channel lengths of 10 μm, 20 μm, 30 μm, 50 μm, 100 μm and 200 μm were produced by this method.

### COMPARATIVE EXAMPLE 1

A top gate thin film transistor device was prepared substantially as described in Example 1, including the UV ozone cleaning step, however, having the channel treatment step omitted.

Transistors having channel lengths of 10 μm, 20 μm, 30 μm, 50 μm, 100 μm and 200 μm were produced by this method.

### COMPARATIVE EXAMPLE 2

A top gate thin film transistor device was prepared substantially as described in Comparative Example 1 but including the an additional step of washing the substrate in isopropanol before applying the semiconducting layer.

Transistors having channel lengths of 10 μm, 20 μm, 30 μm, 50 μm, 100 μm and 200 μm were produced by this method.

Devices were tested in ambient conditions without encapsulation.

Each of the devices so produced was tested to find its saturation mobility, the results of which testing is shown at FIG. 6.

As can be readily seen, the devices manufactured according to Comparative Example 1 and in particular those manufactured in accordance with Comparative Example 2 display a wide spread of mobility values. It is notable that the devices having smaller channel lengths exhibited the lowest mobility.

The devices manufactured according to Example 1 and thus including the self assembled non-polar layer exhibit a far more consistent mobility, whatever the channel length.

The dependence of mobility on channel length is further shown in FIG. 7, which plots the mobilities against channel length for the devices manufactured according to Example 1 and according to Comparative Example 1.

The devices manufactured according to Example 1 clearly exhibit a higher average mobility and maximum mobility at all channel lengths, as well as exhibiting a far lower spread of values, as is exhibited in the ratios of mobilities in devices having 10 μm and 200 μm channel lengths, as shown in Table 1 below.

TABLE 1

| | Average Mobility | | | Maximum Mobility | | |
|---|---|---|---|---|---|---|
| | | | Ratio | | | Ratio |
| Exam- | Mobility | Mobility | 200: | Mobility | Mobility | 200: |
| ple | @10 μm | @200 μm | 10 | @10 μm | @200 μm | 10 |
| 1 | 0.052 | 0.263 | 5.05 | 0.106 | 0.519 | 4.89 |
| CE1 | 0.284 | 0.583 | 2.05 | 0.358 | 0.895 | 2.5 |

The on/off current ratios of some of the devices manufactured according to Example 1 and Comparative Example 1 are shown in FIG. 8. It is clear that the on/off ratio is greater and swing is lower in the devices including the non-polar layer when compared to a device without the layer but having the same channel length.

### EXAMPLE 2

A top gate thin film transistor having both a channel pre-treatment and an electrode contact layer was prepared. The method of preparation was identical to that described in Example 1, further including a step of forming the electrode contact layer immediately after forming the channel contact layer.

The electrode contact layer was formed by preparing a 10 mM concentration of pentafluorobenzenethiol in isopropanol and applying the solution to the source and drain electrodes through a 0.45 μm filter. After around 2 minutes, the solution was removed using a spin coater. The electrodes were then spin washed in isopropanol to remove any remaining unreacted thiol.

Transistors having channel lengths of 10 μm, 20 μm, 30 μm, 50 μm, 100 μm and 200 μm were produced by this method.

### COMPARATIVE EXAMPLE 3

A top gate thin film transistor was prepared as described in Example 2, having an electrode contact layer prepared as described but omitting the channel layer.

Transistors having channel lengths of 10 μm, 20 μm, 30 μm, 50 μm, 100 μm and 200 μm were produced by this method.

FIG. 9 plots the saturation mobility against channel length of devices made according to Examples 1, 2 and 3 and Comparative Example 1.

A consistently high mobility is obtained across all channel lengths by those devices made according to Example 2. This is due to reduced contact resistance, as shown in FIG. 11. Furthermore, without wishing to be bound by any particular theory, it is postulated that enhanced crystallisation of the semiconductor at the source and drain electrodes may also contribute to the enhanced efficiency.

FIG. 10 shows the transfer characteristics of devices made according to Example 2, i.e. having both channel and electrode treatments and having 10 μm and 200 μm lengths. As can be seen, both devices exhibit a low off current and a high on current. Both devices also show a very low sub-threshold swing.

FIG. 11 shows a plot of the average contact resistance against gate bias of devices made according to Examples 1, 2 and 3 and Comparative Example 1. The device of Example 3, having both the channel region layer and the electrode treatment layer exhibited the lowest contact resistance.

### EXAMPLE 4

A top gate thin film transistor was prepared as described in Example 2, with the exception that the electrode contact layer was formed before the channel region layer.

Transistors having channel lengths of 10 μm, 20 μm, 30 μm, 50 μm, 100 μm and 200 μm were produced by this method.

FIG. 12 shows plots of the average and saturation mobilities against channel length for devices made in accordance with Examples 2 and 4.

Although the devices of Example 4, in which the electrode contact layer is applied before the channel region layer, provide improved characteristics over devices simply cleaned with UV and ozone and exhibit similar contact resistances to the devices of Example 2, FIG. 12 shows that the mobility is lower. Without wishing to be bound by any particular theory, the drop in mobility is believed to be caused by the lack of nucleation of crystallisation from the electrodes.

1. A method of forming a top gate transistor comprising the steps of providing a substrate carrying source and drain electrodes defining a channel region therebetween;
treating at least part of the surface of the channel region to reduce its polarity; and
depositing a semiconductor layer in the channel.

2. A method according to claim 1 wherein the treatment comprises the step of forming a layer that covers at least some of the channel region.

3. A method according to claim 2 wherein the layer covers substantially the entire surface of the substrate.

4. A method according to claim 2 wherein the layer comprises a polymer layer.

5. A method according to claim 1 wherein the treatment comprises contacting a reactive species with at least part of the channel region to form a self-assembled layer.

6. A method according to claim 5 wherein the reactive species reacts with polar groups in the channel region to form a residue having at least one non-polar group.

7. A method according to claim 5 wherein the self assembled layer comprises residues comprising the structure: 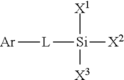
where Ar is an aryl group, L is a linker group or single bond and where X¹ represents a bond to the surface of the substrate and X² and X³ independently represent a bond to the surface of the substrate or a substituent group selected from the group consisting of optionally substituted straight, branched or cyclic alkyl or alkenyl group having from 1 to 10 carbon atoms, or aryl group.

8. A method according to claim 7 wherein both of X² and X³ represent bonds with the surface of the channel region.

9. A method according to claim 7 wherein the linker group L comprises a substituted or unsubstituted, straight, branched or cyclic alkyl group of 1 to 10 carbon atoms.

10. A method according to claim 7 wherein the residues comprise one or more of the structures: 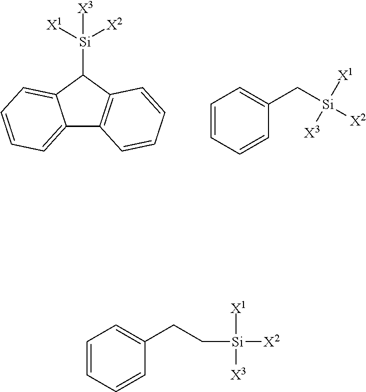
where X¹ represents a bond to the surface of the substrate and X² and X³, if present, independently represent a bond to the surface of the substrate or a substituent group selected from the group consisting of optionally substituted straight, branched or cyclic alkyl or alkenyl group having from 1 to 10 carbon atoms or aryl group.

11. A method according to any of claim 5 wherein the reactive species is bonded to the channel region by reaction of the reactive species with a polar group attached to the channel region, the reaction releasing a leaving group from the reactive species.

12. A method according to claim 5 wherein the reactive species comprises a reactive group that forms a free-radical upon activation, wherein the reactive species is bonded to the channel region by reaction of the reactive group with the surface of the channel region.

13. A method according to claim 1 comprising the step of treating one or both of the source and drain electrodes with a compound for reducing the contact resistance of the electrodes, either before or after the treatment of the channel region, to form an electrode treatment layer covering at least some of the surface of one or both of the source electrode and drain electrode.

14. A method according to claim 13 wherein the electrode treatment layer comprises a polymer layer.

15. A method according to claim 13 wherein the compound comprises a compound capable of chemically binding to the source and drain electrodes to form a self-assembled layer.

16. A method according to claim 15 wherein the compound comprises a thiol or disulfide and the source and drain electrodes comprise gold, silver, copper or alloys thereof.

17. A method according to claim 13 wherein the electrode treatment layer comprises residues presenting a negative dipole moment at the surface of the electrode or electrodes.

18. A method according to claim 17 wherein the electrode treatment layer comprises halogenated or perhalogenated residues.

19. A method according to claim 17 where the electrode treatment layer comprises residues having at least one electron withdrawing group.

20. A method according to claim 13 wherein the electrode treatment layer comprises residues presenting a positive dipole moment at the surface of the electrode or electrodes.

21. A method according to claim 15 wherein the electrode contact layer comprises residues comprising the structures: 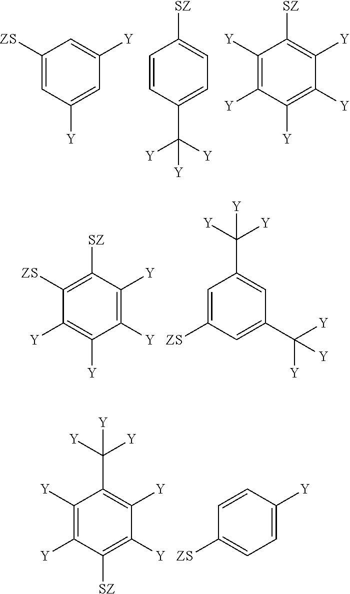
where Y represents an electron withdrawing group, and Z represents a bond between the sulfur atom and the surface of the electrode.

22. A transistor obtained by a method according to claim 1.

23. A top gate transistor having a channel region comprising an organic layer between the substrate and the semiconductor layer.

24. A transistor according to claim 23 wherein the organic layer comprises a layer that covers at least some of the channel region.

25. A transistor according to claim 23 wherein the organic layer comprises a polymer layer.

26. A transistor according to claim 23 wherein the organic layer comprises a self-assembled layer.

27. A transistor according to claim 26 wherein the self-assembled layer comprises residues having at least one non-polar group.

28. A transistor according to claim 27 wherein the self assembled layer comprises residues comprising the structure: 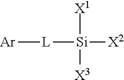
where Ar is an aryl group, L is a linker group or single bond and where X¹ represents a bond to the surface of the substrate and X² and X³ independently represent a bond to the surface of the substrate or a substituent group selected from the group consisting of optionally substituted straight, branched or cyclic alkyl or alkenyl group having from 1 to 10 carbon atoms, or aryl group.

29. A transistor according to claim 28 wherein both of X² and X³ represent bonds with the surface of the substrate.

30. A transistor according to claim 28 wherein the linker group L comprises a substituted or unsubstituted, straight, branched or cyclic alkyl group of 1 to 10 carbon atoms.

31. A transistor according to claim 28 wherein, the residues comprise one or more of the structures: 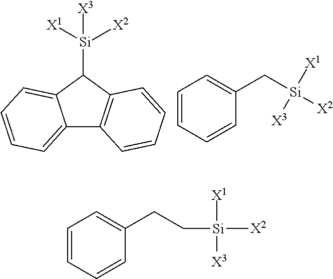
where X¹ represents a bond to the surface of the substrate and X² and X³, if present, independently represent a bond to the surface of the substrate or a substituent group selected from the group: optionally substituted straight, branched or cyclic alkyl or alkenyl group having from 1 to 10 carbon atoms or aryl group.

32. A transistor according to claim 23 having source and drain electrodes, one or both of which electrodes comprise an electrode treatment layer for reducing the contact resistance of the electrodes.

33. A transistor according to claim 32 wherein the electrode treatment layer comprises a polymer layer.

34. A transistor according to claim 32 wherein the electrode treatment layer comprises a self-assembled layer.

35. A transistor according to claim 32 wherein the electrode treatment layer comprises residues presenting a negative dipole moment at the surface of the electrode or electrodes.

36. A transistor according to claim 34 wherein the electrode treatment layer is chemically bound to the source and/or drain electrodes by a sulfur bridge and the source and drain electrodes comprise gold, silver, copper or alloys thereof.

37. A transistor according to claim 35 wherein the electrode treatment layer comprises halogenated or perhalogenated residues.

38. A transistor according to claim 35 where the electrode treatment layer comprises residues having at least one electron withdrawing group.

39. A transistor according to claim 32 wherein the electrode treatment layer comprises residues presenting a positive dipole moment at the surface of the electrode or electrodes.

40. A transistor according to claim 32 wherein the electrode contact layer comprises residues comprising the structures: 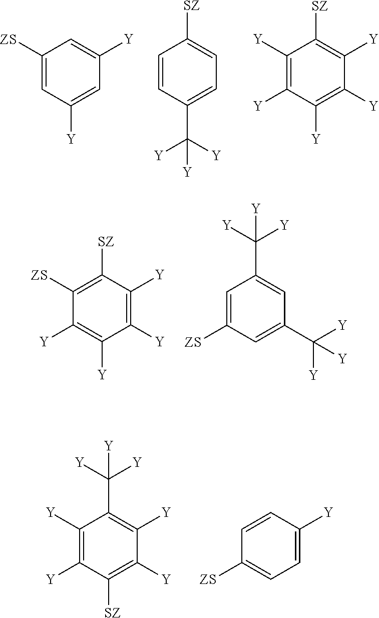
where Y represents an electron withdrawing group, and Z represents a bond between the sulfur atom and the surface of the electrode.

41. A method of forming a top gate transistor according to claim 23 comprising the steps of providing a substrate carrying source and drain electrodes defining a channel region therebetween; depositing an organic layer over the substrate in the channel region; and depositing a semiconductor layer on the organic layer.

42. A method of forming a thin-film transistor comprising the steps of providing source and drain electrodes defining a channel therebetween; treating at least part of the surface of the channel region to reduce the polarity thereof; and subsequently treating at least part of the surface of the source and drain electrodes to reduce the contact resistance thereof.
